(19) United States
(12) Patent Application Publication
(10) Pub. No.: US 2007/0187681 A1
(43) Pub. Date: Aug. 16, 2007

(54) THIN FILM TRANSISTOR

(75) Inventors: Chiun-Hung Chen, Yunlin County (TW); Yu-Chou Lee, Taipei (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: CHUNGHWA PICTURE TUBES, LTD., Taipei (TW)

(21) Appl. No.: 11/740,296

(22) Filed: Apr. 26, 2007

Related U.S. Application Data
(62) Division of application No. 10/906,684, filed on Mar. 2, 2005.

(51) Int. Cl. H01L 29/04

(52) U.S. Cl. 257/59; 257/72

(57) ABSTRACT

A thin film transistor and method of fabrication a thin film transistor and a pixel structure are provided. First, a gate is formed on the substrate. Then, a gate-isolating layer is formed on the substrate to cover the gate electrode. After that, a source/drain is formed on the gate-isolating layer and exposes a portion of the gate-isolating layer above the gate electrode. Then, a channel is formed on the portion of the gate-isolating layer above the gate. The source/drain layer is formed before forming the channel to prevent the channel from over etching as forming the source/drain layer. Therefore, the yields of manufacturing thin film transistor and pixel structure can be improved.

### CROSS-REFERENCE TO RELATED APPLICATION

This application is a divisional of a prior application Ser. No. 10/906,684, filed Mar. 02, 2005, now pending. The entirety of the above-mentioned patent application is hereby incorporated by reference herein and made a part of this specification.

### BACKGROUND OF THE INVENTION

1. Field of the Invention

The present invention generally relates to a semi-conductive device and a method of fabricating thereof. More particularly, the present invention relates to a thin film transistor and methods for fabricating a thin film transistor and a pixel structure.

2. Description of Related Art

Serving as interface between users and electronic devices, flat panel displays include organic electro-luminance display (OLED), plasma display panel (PDP), and thin film transistor liquid crystal display (TFT-LCD), wherein the application of the TFT-LCD is the most familiar.

TFT-LCD comprises a TFT array substrate, a color filter, and a liquid crystal layer. The TFT array substrate has a plurality of pixel units arranged in array, wherein each pixel unit comprises a thin film transistor, and a data line, a scan line, and a pixel electrode, which are electrically connected to the thin film transistor. Each thin film transistor has a gate, a channel, and a source/drain, and serves as a switch device in one of the pixel units.

FIG. 1A˜1E illustrate a prior fabricating process of a thin film transistor. First, referring to FIG. 1A, a gate 120 is formed on a substrate 110. Then, as shown in FIG. 1B, a gate-insulating layer 130 cover the gate 120 is formed. Next, as shown in FIG. 1C, a channel 140 and an ohmic contact material layer 150 are formed on the gate-insulating layer 130. Then, as shown in FIG. 1D, a conductive material layer 160 is formed on the ohmic contact material layer 150. Afterwards, a back channel etching process is performed to define a source/drain as shown in FIG. 1E, and the gate 120, the channel 140 and the source/drain 170 constitute a thin film transistor 100.

In the prior fabricating process of the thin film transistor 100 described above, the ohmic contact material layer 150 and the conductive material layer 160 are consequently formed on the channel 140, and then treated with lithography and etching process to form the source/drain 170. However, in the above fabricating process, the channel 140 must be exposed after the ohmic contact material layer 150 is etched. But owing to the uneven thicknesses of the ohmic contact material layers 150 in different thin film transistors 100, the channels 140 of those thin film transistors 100 with thinner ohmic contact material layer 150 may be over etched and then result in an abnormal electrical characteristic.

### SUMMARY OF THE INVENTION

Accordingly, the present invention is directed to a method of fabricating a thin film transistor, which prevents the channel from being damaged and improves the electrical characteristic of the thin film transistor.

The present invention is directed to a thin film transistor, which is fabricated by the method mentioned above and has superior electrical characteristic.

The present invention is directed to a method of fabricating a pixel structure, which forms the pixel structure with the thin film transistor mentioned above to provide superior operating characteristic.

The present invention discloses a method of fabricating a thin film transistor is provided. First, a gate is formed on a substrate. Then, a gate-insulating layer covering the gate is formed. Next, a source/drain is formed on the gate-insulating layer, wherein a portion of the gate-insulating layer above the gate is exposed by the source/drain. Afterwards, a channel is formed on the portion of the gate-insulating layer above the gate.

According to an embodiment of the present invention, the process of forming the source/drain, for example, forms an ohmic contact layer on the gate-insulating layer first, wherein the ohmic contact layer exposes a portion of the gate-insulating layer above the gate. Then, a source/drain conductive layer is formed on the ohmic contact layer.

According to an embodiment of the present invention, the process of forming the source/drain, for example, forms an ohmic contact material layer and a conductive material layer on the gate-insulating layer consequently. Then, the ohmic contact material layer and the conductive material layer are patterned consequently to expose the portion of the gate-insulating layer above the gate. Wherein the method of patterning the conductive material layer and the ohmic contact material layer includes wet etching or dry etching.

According to an embodiment of the present invention, the material of the gate-insulating layer includes silicon nitride or silicon oxide.

According to an embodiment of the present invention, the material of the channel includes amorphous silicon or poly silicon.

The present invention discloses a thin film transistor, which comprises a gate, a gate-insulating layer, a source/drain, and a channel. The gate is dispose on a substrate, and the gate-insulating layer is disposed on the substrate and covers the gate. The source/drain is disposed on the gate-insulating layer and exposes a portion of the gate-insulating layer above the gate, and the channel is disposed on the portion of the gate-insulating layer.

According to an embodiment of the present invention, the source/drain comprises an ohmic contact layer and a source/drain conductive layer, wherein the ohmic contact layer is disposed on the gate-insulating layer and exposes the portion of the gate-insulating layer above the gate. In addition, the source/drain conductive layer is disposed on the ohmic contact layer.

According to an embodiment of the present invention, the material of the gate-insulating layer includes silicon nitride or silicon oxide.

According to an embodiment of the present invention, the material of the channel includes amorphous silicon or poly silicon.

The present invention discloses a method of fabricating a pixel structure. First, a gate and a scan line are formed on a substrate, wherein the gate is connected to the scan line. Then, a gate-insulating layer covering the gate and the scan line is formed on the substrate. Next, a first source/drain, a second source/drain and a data line are formed on the gate-insulating layer, wherein the first source/drain and the second source/drain are disposed in two sides of the gate-insulating layer above the gate, and the first source/drain is electrically connected to the data line. Then, a channel is formed on the gate-insulating layer above the gate, wherein the gate, the channel, the first source/drain, and the second source/drain constitutes a thin film transistor. After that, a passivation layer is formed on the substrate to cover the thin film transistor and the data line, wherein the passivation layer has a contact hole to expose a portion of the second source/drain. Then, a pixel electrode is formed on the passivation layer, wherein the pixel electrode is electrically connected to the second source/drain through the contact hole.

According to an embodiment of the present invention, the process of forming the source/drain, for example, forms an ohmic contact layer on the gate-insulating layer first, wherein the ohmic contact layer exposes a portion of the gate-insulating layer above the gate. Then, a source/drain conductive layer is formed on the ohmic contact layer.

According to an embodiment of the present invention, the process of forming the source/drain, for example, forms an ohmic contact material layer and a conductive material layer on the gate-insulating layer consequently. Then, the ohmic contact material layer and the conductive material layer are patterned consequently to expose the portion of the gate-insulating layer above the gate. Wherein the method of patterning the conductive material layer and the ohmic contact material layer includes wet etching or dry etching.

According to an embodiment of the present invention, the material of the gate-insulating layer includes silicon nitride or silicon oxide.

According to an embodiment of the present invention, the material of the channel includes amorphous silicon or poly silicon.

According to an embodiment of the present invention, the material of the passivation layer includes silicon nitride or silicon oxide.

According to an embodiment of the present invention, the material of the pixel electrode includes indium tin oxide (ITO) or indium zinc oxide (IZO).

The present invention forms the source/drain before forming the channel to avoid the channel from over etching and then improves the productive yields of the thin film transistor and the pixel structure.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A˜1E illustrate a prior fabricating process of a thin film transistor.

FIG. 2A˜2E illustrate a fabricating process of a thin film transistor according to an embodiment of the present invention.

FIG. 3 is a sectional drawing showing another kind of thin film transistor according to an embodiment of the present invention.

FIG. 4 is a schematic drawing showing a pixel structure according to the present invention.

FIG. 5A˜5E are sectional drawings along line A-A′ showing a manufacturing process of the pixel structure in FIG. 4.

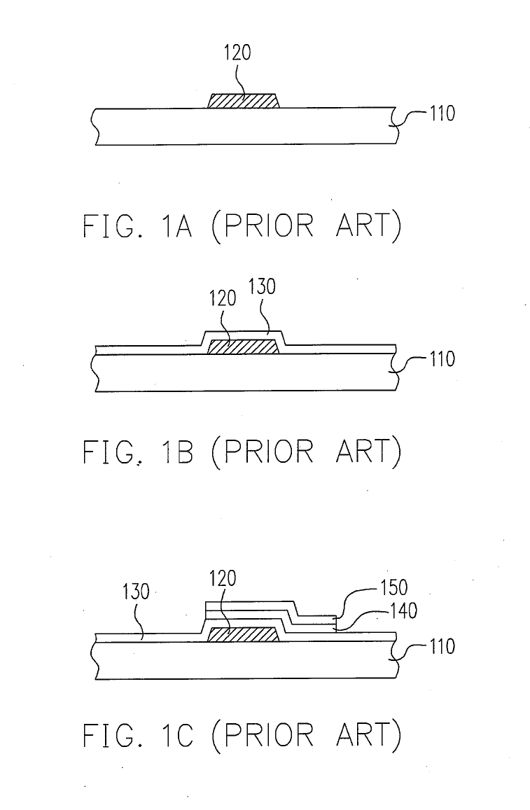

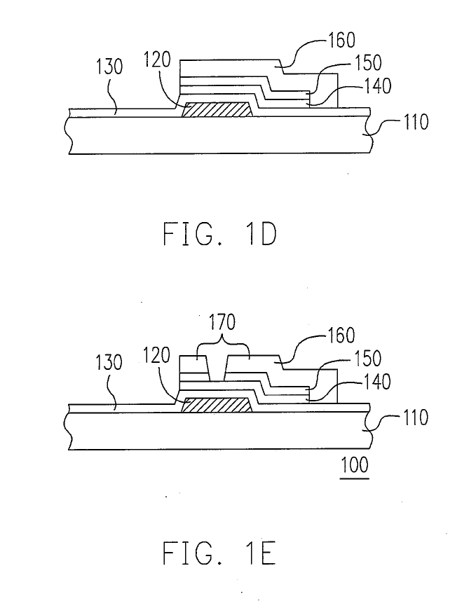

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

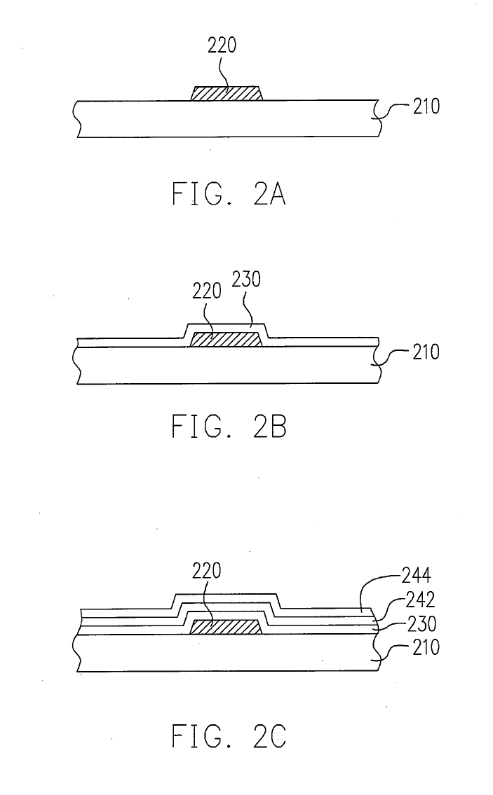

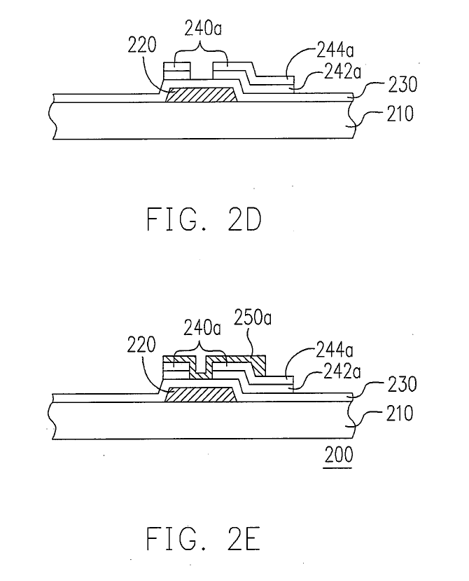

FIG. 2A˜2E illustrate a fabricating process of a thin film transistor according to an embodiment of the present invention. First, referring to FIG. 2A, a gate 220 is formed on a substrate 210. The method of forming the gate 220, for example, a conductive layer (not shown) is deposited on the substrate 210 first, and then the conductive layer (not shown) is patterned with a mask (not shown) by lithography and etching process to form the gate 220 on the substrate 210. Being familiar and well known to those skilled in the art, the lithography and etching process mentioned above will not be described again in unnecessary details.

Referring to FIG. 2B, a gate-insulating layer 230 covering the gate 220 is formed on the substrate 210, wherein the method of forming the gate-insulating layer 230 includes physical vapour deposition (PVD) or chemical vapour deposition (CVD), and the material of the gate-insulating layer 230, for example, is silicon nitride or silicon oxide.

Next, referring to FIG. 2C and FIG. 2D, a source/drain 240a is formed on the gate-insulating layer 230, and the source/drain 240a exposes a portion of the gate-insulating layer 230 above the gate 220. In an embodiment, the method of forming source/drain 240a is described as follows.

Referring to FIG. 2C, an ohmic contact material layer 242 and a conductive material layer 244 are formed on the gate-insulating layer 230 consequently, wherein the method of forming the ohmic contact material layer 242 and the conductive material layer 244 is, for example, physical vapour deposition (PVD) or chemical vapour deposition (CVD). Then, the ohmic contact material layer 242 and the conductive material layer 244 are patterned consequently to form the source/drain 240a as shown in FIG. 2D, wherein the source/drain 240a exposes the portion of the gate-insulating layer 230 above the gate 220. In an embodiment, the method of patterning the ohmic contact material layer 242 and the conductive material layer 244 may be wet etching or dry etching. For example, a wet etching process is performed to the conductive material layer 244 by using a patterned photoresist layer (not shown) as a mask to form a source/drain conductive layer 244a, and a dry etching process is then performed to the ohmic contact material layer 242 by using the same patterned photoresist layer (not shown) as the mask to form an ohmic contact layer 242a, wherein the ohmic contact layer 242a and the source/drain conductive layer 244a constitute the source/drain 240a.

Next, referring to FIG. 2E, a channel 250a is formed on the portion of the gate-insulating layer 230 above the gate 220. In an embodiment, the method of forming the channel 250a, for example, deposits a channel material layer (not shown) on the gate-insulating layer 230, wherein the channel material layer (not shown) covers the source/drain 240a. Then, a lithography and etching process is performed to the channel material layer (not shown) to form the channel 250a as shown in FIG. 2E. The material of channel 250a may be amorphous silicon or poly silicon.

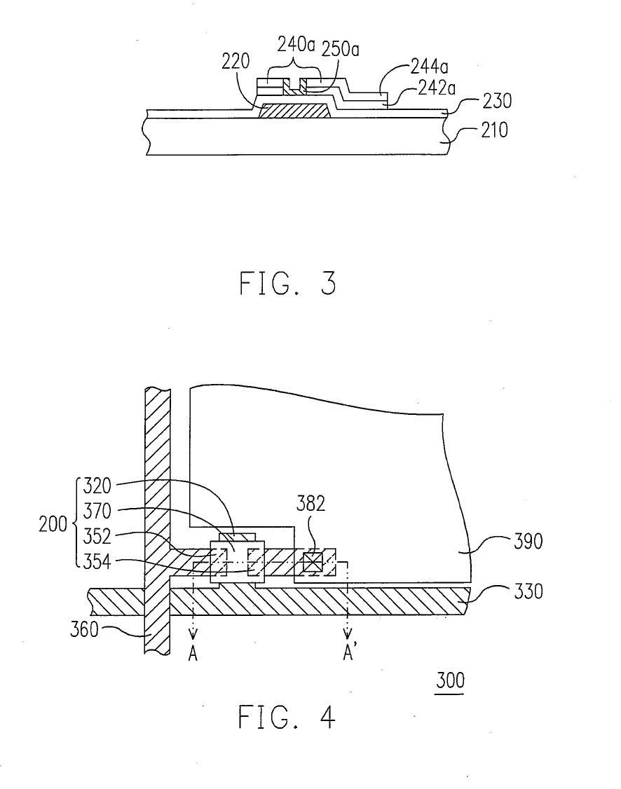

As shown in FIG. 3, in the lithography and etching process mentioned above, the channel material layer (not shown) on the source/drain 240a can also be removed to form the channel 250a only on the portion of the gate-insulating layer 230 above the gate 220. Therefore, the present invention does not limit whether the source/drain 240a is covered by the channel 250a, or not.

A detail description of a thin film transistor formed by the above process is provided in the following paragraph. Referring to FIG. 2E, the thin film transistor 200 comprises the gate 220, the gate-insulating layer 230, the source/drain 240a, and the channel 250a, wherein the gate 220 is disposed on the substrate 210, and the gate-insulating layer 230 is disposed on the substrate 210 and covers the gate 220. The source/drain 240a is disposed on the gate-insulating layer 230 and exposes the portion of the gate-insulating layer 230 above the gate 220, and the channel 250a is disposed on the portion of the gate-insulating layer 230 above the gate 220.

In an embodiment, the source/drain 240a comprises the ohmic contact layer 242a and the source/drain conductive layer 244a, wherein the ohmic contact layer 242a is disposed on the gate-insulating layer 230 and exposes the portion of the gate-insulating layer 230 above the gate 220. In addition, the source/drain conductive layer 244a is disposed on the ohmic contact layer 242a. The material of the gate-insulating layer 230 may be silicon nitride or silicon oxide, and the material of the channel 250a may be amorphous silicon or poly silicon.

The present invention forms the source/drain 240a before forming the channel 250a to avoid the channel 250a from over etching as forming the source/drain 240a. Therefore the channel 250a can provides superior electrical characteristic.

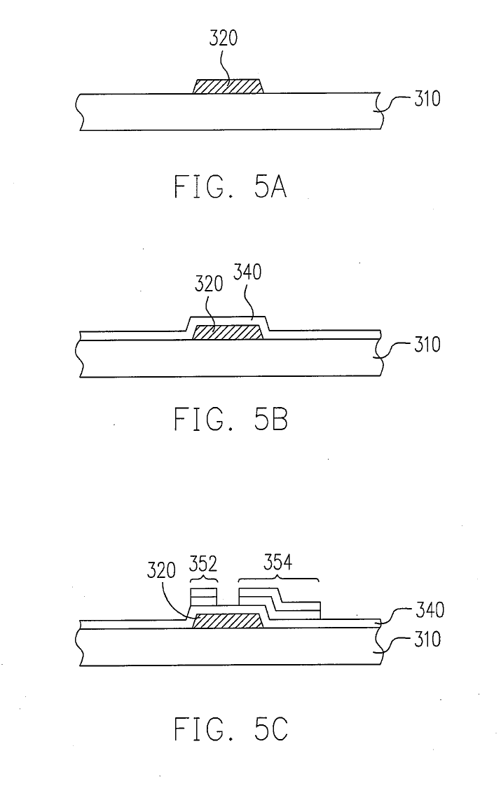

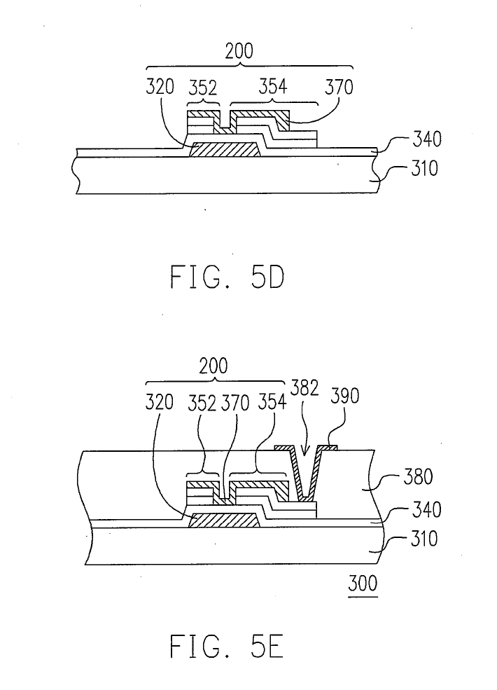

FIG. 4 is a schematic drawing showing a pixel structure according to the present invention, and FIG. 5A˜5E are sectional drawings along line A-A′ showing a manufacturing process of the pixel structure in FIG. 4.

First, referring to FIG. 4 and FIG. 5A, a gate 320 and a scan line 330 are formed on a substrate 310, wherein the gate 320 is connected to the scan line 330. Then, referring to FIG. 4 and FIG. 5B, a gate-insulating layer 340 covering the gate 320 and the scan line 330 is formed on the substrate 310. The method of forming the gate-insulating layer 340 may be physical vapour deposition (PVD) or chemical vapour deposition (CVD), and the material of the gate-insulating layer 340 may be silicon nitride or silicon oxide.

Next, referring to FIG. 4 and FIG. 5C, a first source/drain 350, a second source/drain 354, and a data line 360 are formed on the gate-insulating layer 340, wherein the first source/drain 352 and the second source/drain 354 are disposed on the gate-insulating layer 340 above two sides of the gate 320, and the first source/drain 352 is electrically connected to the data line 360. Being similar to the process of forming source/drain 240a in the thin film transistor 200 mentioned above, the process of forming the first source/drain 352 and the second source/drain 354 will not be mentioned again.

Then, referring to FIG. 4 and FIG. 5D, a channel 370 is formed on the gate-insulating layer 340 above the gate 320. In an embodiment, the method of forming the channel 370, for example, deposits a channel material layer (not shown) on the gate-insulating layer 340 to covers the first source/drain 352 and the second source/drain 354. Then, a lithography and etching process is performed to the channel material layer (not shown) to form the channel 370 on a portion of the gate-insulating layer 340 above the gate 320, wherein the material of the channel 370 may be amorphous silicon or poly silicon. The gate 320, the channel 370, the first source/drain 352, and the second source/drain 354 constitute the thin film transistor 200 mentioned in the above embodiment.

Then, referring to FIG. 4 and FIG. 5E, a passivation layer 380 is formed on the substrate 310, and the passivation layer 380 has a contact hole 382 to expose a portion of the second source/drain 354. The material of the passivation layer 380 may be silicon nitride or silicon oxide, which is deposited on the substrate 310 by physical vapour deposition (PVD) or chemical vapour deposition (CVD), and then patterned by a lithography and etching process to form a contact hole 382, which exposes the portion of the second source/drain 354.

Next, referring to FIG. 4 and FIG. 5E, a pixel electrode 390 is formed on the passivation layer 380 and electrically connected to the second source/drain 354 through the contact hole 382. The material of the pixel electrode 380 may be indium tin oxide (ITO) or indium zinc oxide (IZO), and the forming method thereof may be sputtering. After the process mentioned above, a pixel structure 300 is formed.

The method of fabricating the pixel structure 300 changes the sequence of forming the first source/drain 352, the second source/drain 354, and the channel 370 to prevent the channel 370 from over etching as forming the first source/drain 352 and the second source/drain 354. Therefore, the present invention provides the pixel structure 300 with superior electrical characteristic.

Accordingly, the present invention has following merits.
1. By forming the source/drain before forming the channel, the channel can be protected from over etching in the process of forming the source/drain.
2. The channel will not be etched and damaged, so the thin film transistor of the present invention has superior electrical characteristic.
3. The thin film transistor and the method of fabricating the thin film transistor and the pixel structure provide higher productive yields.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A thin film transistor, comprising:
a gate, disposed on a substrate;
a gate-insulating layer, disposed on the substrate, wherein the gate-insulating layer covers the gate;
a source/drain, disposed on the gate-insulating layer, wherein the source/drain exposes a portion of the gate-insulating layer above the gate; and
a channel, disposed on the portion of the gate-insulating layer above the gate.

2. The thin film transistor according to claim 1, wherein the source/drain comprises:
an ohmic contact layer, disposed on the gate-insulating layer, wherein the ohmic contact layer exposes the portion of the gate-insulating layer above the gate; and
a source/drain conductive layer, disposed on the ohmic contact layer.

3. The thin film transistor according to claim 1, wherein the material of the gate-insulating layer comprises silicon nitride or silicon oxide.

4. The thin film transistor according to claim 1, wherein the material of the channel comprises amorphous silicon or poly silicon.
